(19) United States
(12) Patent Application Publication
(10) Pub. No.: US 2021/0183620 A1
(43) Pub. Date: Jun. 17, 2021

(54) CHAMBER WITH INDUCTIVE POWER SOURCE

(71) Applicant: Applied Materials, Inc., Santa Clara, CA (US)

(72) Inventors: Wei Tian, Sunnyvale, CA (US); Toan Q. Tran, San Jose, CA (US); Dmitry Lubomirsky, Cupertino, CA (US); Greg Toland, San Jose, CA (US); Satoru Kobayashi, Sunnyvale, CA (US)

(73) Assignee: Applied Materials, Inc., Santa Clara, CA (US)

(21) Appl. No.: 16/713,615

(22) Filed: Dec. 13, 2019

(51) Int. Cl. H01J 37/32; H01L 21/67

(52) U.S. Cl. CPC H01J 37/3244; H01L 21/67069; H01J 2237/334; H01J 37/32091; H01J 37/321

(57) ABSTRACT

Exemplary processing chambers may include a chamber housing at least partially defining an interior region of the semiconductor processing chamber. The chambers may include a showerhead positioned within the chamber housing. The showerhead may at least partially separate the interior region into a remote region and a processing region. Sidewalls of the chamber housing may at least partially define the processing region. The chambers may include a substrate support extending into the processing region and configured to support a substrate. The chambers may include an inductively-coupled plasma source positioned between the showerhead and the substrate support. The inductively-coupled plasma source may include a conductive material disposed within a dielectric material. The inductively-coupled plasma source may form a portion of the sidewalls of the chamber housing.

### TECHNICAL FIELD

The present technology relates to semiconductor systems, processes, and equipment. More specifically, the present technology relates to processing chambers that may include an inductively-coupled plasma source within the chamber.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials.

Etch processes may be termed wet or dry based on the materials used in the process. A wet HF etch preferentially removes silicon oxide over other dielectrics and materials. However, wet processes may have difficulty penetrating some constrained trenches and also may sometimes deform the remaining material. Dry etches produced in local plasmas formed within the substrate processing region can penetrate more constrained trenches and exhibit less deformation of delicate remaining structures. However, local plasmas may damage the substrate through the production of electric arcs as they discharge.

Thus, there is a need for improved systems and methods that can be used to produce high quality devices and structures. These and other needs are addressed by the present technology.

### SUMMARY

Exemplary processing chambers may include a chamber housing at least partially defining an interior region of the semiconductor processing chamber. The chambers may include a showerhead positioned within the chamber housing. The showerhead may at least partially separate the interior region into a remote region and a processing region. Sidewalls of the chamber housing may at least partially define the processing region. The chambers may include a substrate support extending into the processing region and configured to support a substrate. The chambers may include an inductively-coupled plasma source positioned between the showerhead and the substrate support. The inductively-coupled plasma source may include a conductive material disposed within a dielectric material. The inductively-coupled plasma source may form a portion of the sidewalls of the chamber housing.

In some embodiments, the dielectric material may be selected from materials including aluminum oxide, yttrium oxide, single crystalline silicon, or quartz. The substrate support may include an electrode operable to form a capacitively-coupled plasma within the processing region. The showerhead may be coupled with electrical ground and operable as a second electrode configured to produce a capacitively-coupled plasma within the processing region. The chambers may include a liner extending across the showerhead and along the sidewalls of the chamber housing. The liner may extend across the inductively-coupled plasma source. The liner may be or include a dielectric material selected from materials including aluminum oxide, yttrium oxide, single crystalline silicon, or quartz. The liner may extend across a surface of the showerhead facing the processing region. The liner may define a plurality of apertures through the liner. The conductive material may be configured in a coil extending vertically within the dielectric material for at least two complete turns of the conductive material. The chambers may include a spacer positioned between the showerhead and the inductively-coupled plasma source.

Some embodiments of the present technology may encompass semiconductor processing chambers. The chambers may include a chamber housing at least partially defining a processing region of the semiconductor processing chamber. The chamber housing may include a lid assembly defining an inlet for receiving precursors into the semiconductor processing chamber. The chamber housing may include sidewalls extending about the processing region. The chambers may include a pedestal extending within the processing region of the semiconductor processing chamber and configured to support a substrate for processing. The chambers may include a showerhead positioned within the chamber housing. The showerhead may be positioned between the lid assembly and the pedestal. The chambers may include an inductively-coupled plasma source positioned between the showerhead and the pedestal. The inductively-coupled plasma source may include a conductive material within a dielectric material.

In some embodiments the inductively-coupled plasma source may include an annular component disposed as a portion of the chamber housing. The inductively-coupled plasma source may be seated on the sidewalls of the chamber housing. The chambers may include a liner extending radially inward of the inductively-coupled plasma source. The liner may be seated on the sidewalls of the chamber housing. The liner may include a first portion extending across the inductively-coupled plasma source. The liner may include a second portion extending across the showerhead. The second portion may define a plurality of apertures through the liner. A gap may be defined between the showerhead and the second portion of the liner. The pedestal may include an electrode operable to form a capacitively-coupled plasma within the processing region. The showerhead may be coupled with electrical ground and operable as a second electrode configured to produce a capacitively-coupled plasma within the processing region. The sidewalls of the chamber housing may be coupled with electrical ground.

Some embodiments of the present technology may encompass semiconductor processing chambers. The chambers may include a chamber housing at least partially defining a processing region of the semiconductor processing chamber. The chamber housing may include a lid, and the chamber housing may include sidewalls. The chambers may include a pedestal extending within the processing region of the semiconductor processing chamber and configured to support a substrate for processing. The chambers may include a showerhead positioned within the chamber housing. The showerhead may be positioned between the lid and the pedestal. The chambers may include an inductively-coupled plasma source positioned between the showerhead and the pedestal. The inductively-coupled plasma source may include a conductive material within a dielectric material. The inductively-coupled plasma source may be seated on the sidewalls of the chamber housing. The chambers may include a liner seated on the sidewalls of the chamber housing radially inward of the inductively-coupled plasma source.

Such technology may provide numerous benefits over conventional systems and techniques. For example, inductive sources according to the present technology may reduce component sputtering from the electrodes. Additionally, plasma sources of the present technology may allow decoupling of plasma ion energy from ion density. The inductive plasma source may also significantly increase plasma density, which may increase etch rate or throughput. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary processing chamber according to some embodiments of the present technology.

FIG. 3 shows a schematic cross-sectional view of an exemplary processing chamber according to some embodiments of the present technology.

FIG. 4 shows operations of an exemplary etching method according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include additional or exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

The present technology includes systems and components for semiconductor processing including tuned etch processes. Certain processing chambers available may include multiple plasma mechanisms, such as one at the wafer level as well as a remote plasma source. Plasma at the wafer level may often be formed via a capacitively-coupled plasma formed between two electrodes. One or both of these electrodes may be or include additional chamber components, such as showerheads, pedestals, or chamber walls. However, even at relatively low-level plasma power and chamber pressures, such as 50 W power at 20 mTorr, the induced voltage on the electrodes may be hundreds of volts. The plasma sheath formed may energize ions which may bombard chamber components causing sputtering of chamber sidewalls and the electrodes themselves, which may introduce the sputtered particulate material onto the wafer. These particulates may cause uniformity issues across the wafer, and may deposit conductive material that can cause short circuiting of the finally produced structure. Consequently, many conventional technologies may be limited with the wafer-level plasma formation to low power processing, which may be used to trim or clean features, with limited performance of broader etch activities with this process.

Conventional technologies may have addressed this sputtering issue by seasoning the chamber components with a polymer coating, such as a carbon-containing coating or a silicon-containing coating. Such a polymer layer may operate as a passivation layer on the surfaces of the capacitively-coupled source electrodes. However, such a coating may be difficult to apply uniformly to a showerhead or component, may not have complete coverage, and may still be degraded over time, leading to the polymeric material being deposited on the wafer.

The present technology may overcome these issues by incorporating an inductively-coupled plasma (“ICP”) source within the chamber itself. The ICP source may produce voltages much lower than a capacitively-coupled plasma source of the same power, which may at least partially resolve electrode sputtering. Additionally, because the ICP source operates differently from the two plates of the capacitively-coupled source, which may still be incorporated within the chamber, plasma ion density and ion energy may be decoupled in exemplary chambers according to the present technology. This may allow improved plasma tuning and feature modification over conventional technologies. By utilizing an ICP source, higher power may be applied, which may facilitate increased etch rates, allowing broader application of chambers incorporating sources according to embodiments of the present technology.

Although the remaining disclosure will routinely identify specific etching processes utilizing the disclosed technology, it will be readily understood that the systems and methods are equally applicable to deposition and cleaning processes as may occur in the described chambers. Accordingly, the technology should not be considered to be so limited as for use with etching processes alone. The disclosure will discuss one possible chamber that may include ICP sources according to embodiments of the present technology before additional variations and adjustments to this system according to embodiments of the present technology are described.

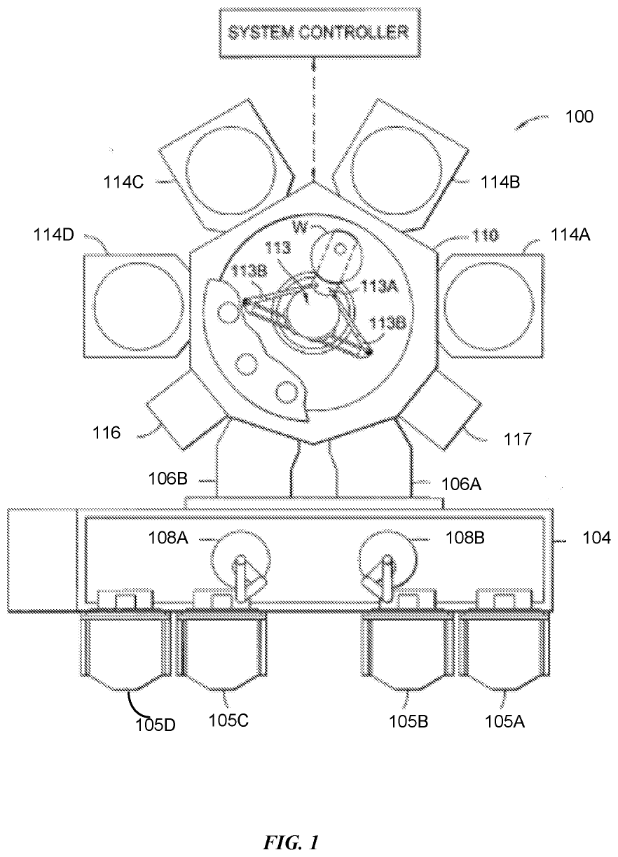

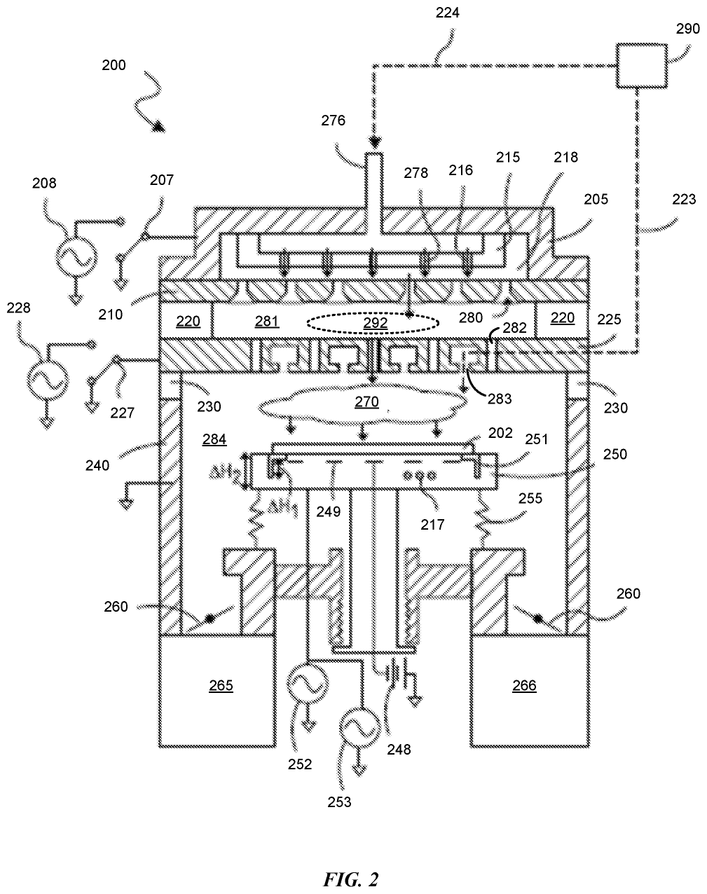

FIG. 1 shows a top plan view of one embodiment of a processing system 100 of deposition, etching, baking, and curing chambers according to embodiments. The processing tool 100 depicted in FIG. 1 may contain a plurality of process chambers, 114A-D, a transfer chamber 110, a service chamber 116, an integrated metrology chamber 117, and a pair of load lock chambers 106A-B. The process chambers may include structures or components similar to those described in relation to FIG. 2, as well as additional processing chambers.

To transport substrates among the chambers, the transfer chamber 110 may contain a robotic transport mechanism 113. The transport mechanism 113 may have a pair of substrate transport blades 113A attached to the distal ends of extendible arms 113B, respectively. The blades 113A may be used for carrying individual substrates to and from the process chambers. In operation, one of the substrate transport blades such as blade 113A of the transport mechanism 113 may retrieve a substrate W from one of the load lock chambers such as chambers 106A-B and carry substrate W to a first stage of processing, for example, an etching process as described below in chambers 114A-D. If the chamber is occupied, the robot may wait until the processing is complete and then remove the processed substrate from the chamber with one blade 113A and may insert a new substrate with a second blade (not shown). Once the substrate is processed, it may then be moved to a second stage of processing. For each move, the transport mechanism 113 generally may have one blade carrying a substrate and one blade empty to execute a substrate exchange. The transport mechanism 113 may wait at each chamber until an exchange can be accomplished.

Once processing is complete within the process chambers, the transport mechanism 113 may move the substrate W from the last process chamber and transport the substrate W to a cassette within the load lock chambers 106A-B. From the load lock chambers 106A-B, the substrate may move into a factory interface 104. The factory interface 104 generally may operate to transfer substrates between pod loaders 105A-D in an atmospheric pressure clean environment and the load lock chambers 106A-B. The clean environment in factory interface 104 may be generally provided through air filtration processes, such as HEPA filtration, for example. Factory interface 104 may also include a substrate orienter/aligner (not shown) that may be used to properly align the substrates prior to processing. At least one substrate robot, such as robots 108A-B, may be positioned in factory interface 104 to transport substrates between various positions/locations within factory interface 104 and to other locations in communication therewith. Robots 108A-B may be configured to travel along a track system within factory interface 104 from a first end to a second end of the factory interface 104.

The processing system 100 may further include an integrated metrology chamber 117 to provide control signals, which may provide adaptive control over any of the processes being performed in the processing chambers. The integrated metrology chamber 117 may include any of a variety of metrological devices to measure various film properties, such as thickness, roughness, composition, and the metrology devices may further be capable of characterizing grating parameters such as critical dimensions, sidewall angle, and feature height under vacuum in an automated manner.

Turning now to FIG. 2 is shown a cross-sectional view of an exemplary process chamber system 200 according to the present technology. Chamber 200 may be used, for example, in one or more of the processing chamber sections 114 of the system 100 previously discussed. Generally, the etch chamber 200 may include a first capacitively-coupled plasma source to implement an ion milling operation and a second capacitively-coupled plasma source to implement an etching operation and to implement an optional deposition operation. In embodiments explained further below, the chamber may further include an inductively-coupled plasma source to perform additional ion etching operations. The chamber 200 may include grounded chamber walls 240 surrounding a chuck 250. In embodiments, the chuck 250 may be an electrostatic chuck that clamps the substrate 202 to a top surface of the chuck 250 during processing, though other clamping mechanisms as would be known may also be utilized. The chuck 250 may include an embedded heat exchanger coil 217. In the exemplary embodiment, the heat exchanger coil 217 includes one or more heat transfer fluid channels through which heat transfer fluid, such as an ethylene glycol/water mix, may be passed to control the temperature of the chuck 250 and ultimately the temperature of the substrate 202.

The chuck 250 may include a mesh 249 coupled to a high voltage DC supply 248 so that the mesh 249 may carry a DC bias potential to implement the electrostatic clamping of the substrate 202. The chuck 250 may be coupled with a first RF power source and in one such embodiment, the mesh 249 may be coupled with the first RF power source so that both the DC voltage offset and the RF voltage potentials are coupled across a thin dielectric layer on the top surface of the chuck 250. In the illustrative embodiment, the first RF power source may include a first and second RF generator 252, 253. The RF generators 252, 253 may operate at any industrially utilized frequency, however in the exemplary embodiment the RF generator 252 may operate at 60 MHz to provide advantageous directionality. Where a second RF generator 253 is also provided, the exemplary frequency may be 2 MHz.

With the chuck 250 to be RF powered, an RF return path may be provided by a first showerhead 225, which may include a dual channel showerhead. The first showerhead 225 may be disposed above the chuck to distribute a first feed gas into a first chamber region 284 defined by the first showerhead 225 and the chamber wall 240. As such, the chuck 250 and the first showerhead 225 form a first RF coupled electrode pair to capacitively energize a first plasma 270 of a first feed gas within a first chamber region 284. A DC plasma bias, or RF bias, resulting from capacitive coupling of the RF powered chuck may generate an ion flux from the first plasma 270 to the substrate 202, such as argon or helium ions to provide an ion milling plasma. The first showerhead 225 may be grounded or alternately coupled with an RF source 228 having one or more generators operable at a frequency other than that of the chuck 250, e.g., 13.56 MHz or 60 MHz. In the illustrated embodiment the first showerhead 225 may be selectably coupled to ground or the RF source 228 through the relay 227 which may be automatically controlled during the etch process, for example by a controller communicatively coupled with the chamber. In some embodiments, chamber 200 may not include showerhead 225 or dielectric spacer 220, and may instead include only baffle 215 and showerhead 210 described further below.

As further illustrated in the figure, the etch chamber 200 may include a pump stack capable of high throughput at low process pressures. In embodiments, at least one turbo molecular pump 265, 266 may be coupled with the first chamber region 284 through one or more gate valves 260 and disposed below the chuck 250, opposite the first showerhead 225. The turbo molecular pumps 265, 266 may be any commercially available pumps having suitable throughput and more particularly may be sized appropriately to maintain process pressures below or about 10 mTorr or below or about 5 mTorr at the desired flow rate of the first feed gas, e.g., 50 to 500 sccm of argon where argon is the first feedgas. In the embodiment illustrated, the chuck 250 may form part of a pedestal which is centered between the two turbo pumps 265 and 266, however in alternate configurations chuck 250 may be on a pedestal cantilevered from the chamber wall 240 with a single turbo molecular pump having a center aligned with a center of the chuck 250.

Disposed above the first showerhead 225 may be a second showerhead 210. In one embodiment, during processing, the first feed gas source, for example, argon or helium delivered from gas distribution system 290 may be coupled with a gas inlet 276, and the first feed gas flowed through a plurality of apertures 280 extending through second showerhead 210, into the second chamber region 281, and through a plurality of apertures 282 extending through the first showerhead 225 into the first chamber region 284. An additional flow distributor or baffle 215 having apertures 278 may further distribute a first feed gas flow 216 across the diameter of the etch chamber 200 through a distribution region 218. In an alternate embodiment, the first feed gas may be flowed directly into the first chamber region 284 via apertures 283 which are isolated from the second chamber region 281 as denoted by dashed line 223.

Chamber 200 may additionally be reconfigured from the state illustrated to perform an etching operation. A secondary electrode 205 may be disposed above the first showerhead 225 with a second chamber region 281 there between. The secondary electrode 205 may further form a lid or top plate of the etch chamber 200. The secondary electrode 205 and the first showerhead 225 may be electrically isolated by a dielectric ring 220 and form a second RF coupled electrode pair to capacitively discharge a second plasma 292 of a second feed gas within the second chamber region 281. Advantageously, the second plasma 292 may not provide a significant RF bias potential on the chuck 250. At least one electrode of the second RF coupled electrode pair may be coupled with an RF source for energizing an etching plasma. The secondary electrode 205 may be electrically coupled with the second showerhead 210. In an exemplary embodiment, the first showerhead 225 may be coupled with a ground plane or floating and may be coupled to ground through a relay 227 allowing the first showerhead 225 to also be powered by the RF power source 228 during the ion milling mode of operation. Where the first showerhead 225 is grounded, an RF power source 208, having one or more RF generators operating at 13.56 MHz or 60 MHz, for example, may be coupled with the secondary electrode 205 through a relay 207 which may allow the secondary electrode 205 to also be grounded during other operational modes, such as during an ion milling operation, although the secondary electrode 205 may also be left floating if the first showerhead 225 is powered.

A second feed gas source, such as nitrogen trifluoride, and a hydrogen source, such as ammonia, may be delivered from gas distribution system 290, and coupled with the gas inlet 276 such as via dashed line 224. In this mode, the second feed gas may flow through the second showerhead 210 and may be energized in the second chamber region 281. Reactive species may then pass into the first chamber region 284 to react with the substrate 202. As further illustrated, for embodiments where the first showerhead 225 is a multi-channel showerhead, one or more feed gases may be provided to react with the reactive species generated by the second plasma 292. In one such embodiment, a water source may be coupled with the plurality of apertures 283. Additional configurations may also be based on the general illustration provided, but with various components reconfigured. For example, flow distributor or baffle 215 may be a plate similar to the second showerhead 210, and may be positioned between the secondary electrode 205 and the second showerhead 210.

As any of these plates may operate as an electrode in various configurations for producing plasma, one or more annular or other shaped spacer may be positioned between one or more of these components, similar to dielectric ring 220. Second showerhead 210 may also operate as an ion suppression plate in embodiments, and may be configured to reduce, limit, or suppress the flow of ionic species through the second showerhead 210, while still allowing the flow of neutral and radical species. One or more additional showerheads or distributors may be included in the chamber between first showerhead 225 and chuck 250. Such a showerhead may take the shape or structure of any of the distribution plates or structures previously described. Also, in embodiments a remote plasma unit (not shown) may be coupled with the gas inlet to provide plasma effluents to the chamber for use in various processes.

In some embodiments, the chuck 250 may be movable along the distance H2 in a direction normal to the first showerhead 225. The chuck 250 may be on an actuated mechanism surrounded by a bellows 255, or the like, to allow the chuck 250 to move closer to or farther from the first showerhead 225 as a means of controlling heat transfer between the chuck 250 and the first showerhead 225, which may be at an elevated temperature of 80° C.-150° C., or more. As such, an etch process may be implemented by moving the chuck 250 between first and second predetermined positions relative to the first showerhead 225. Alternatively, the chuck 250 may include a lifter 251 to elevate the substrate 202 off a top surface of the chuck 250 by distance H1 to control heating by the first showerhead 225 during the etch process. In other embodiments, where the etch process is performed at a fixed temperature such as about 90-110° C. for example, chuck displacement mechanisms may be avoided. A system controller (not shown) may alternately energize the first and second plasmas 270 and 292 during the etching process by alternately powering the first and second RF coupled electrode pairs automatically.

The chamber 200 may also be reconfigured to perform a deposition operation. A plasma 292 may be generated in the second chamber region 281 by an RF discharge which may be implemented in any of the manners described for the second plasma 292. Where the first showerhead 225 is powered to generate the plasma 292 during a deposition, the first showerhead 225 may be isolated from a grounded chamber wall 240 by a dielectric spacer 230 so as to be electrically floating relative to the chamber wall. In the exemplary embodiment, an oxidizer feed gas source, such as molecular oxygen, may be delivered from gas distribution system 290, and coupled with the gas inlet 276. In embodiments where the first showerhead 225 is a multi-channel showerhead, any silicon-containing precursor, such as OMCTS for example, may be delivered from gas distribution system 290, and directed into the first chamber region 284 to react with reactive species passing through the first showerhead 225 from the plasma 292. Alternatively the silicon-containing precursor may also be flowed through the gas inlet 276 along with the oxidizer.

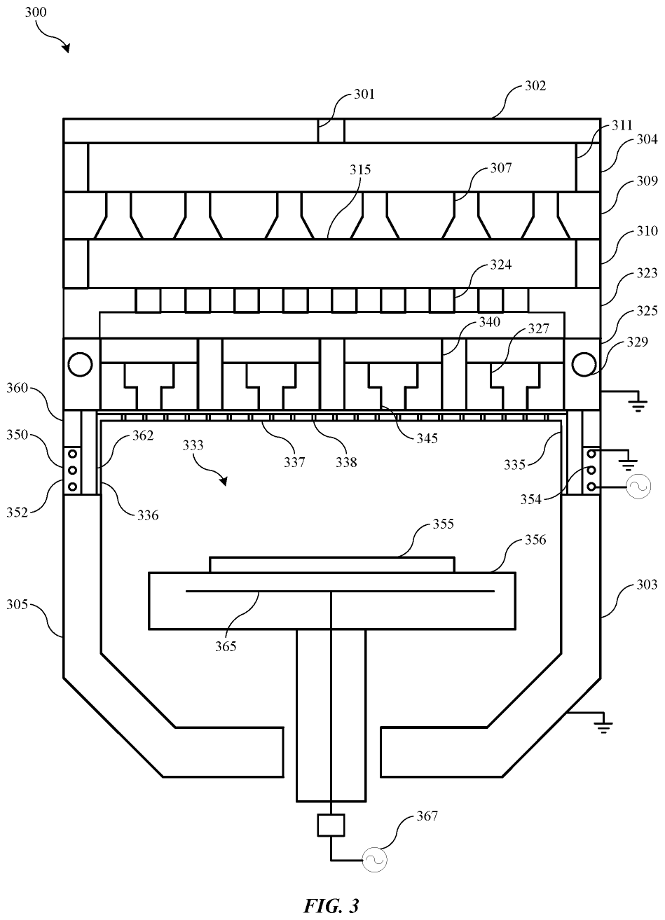

Turning to FIG. 3 is shown a simplified schematic of processing system 300 according to some embodiments of the present technology. The chamber of system 300 may include any of the components as previously discussed with relation to FIG. 2, and may show further details of chamber 200 described previously. As discussed above, the present technology may incorporate an inductively-coupled plasma (“ICP”) source into the chamber 200 described above, or any other chamber, which may benefit from an ICP source. As discussed previously, in order to increase ion density with capacitively-coupled sources, power is often increased, which may create high sheath voltages that may cause sputtering and bombardment of chamber components. However, an ICP source better couples power into the plasma, and with increased efficiency may produce much greater ion density at reduced power. The increased ion density produced may be at relatively low energy or flux due to the nature of the inductively-generated plasma, and may not be characterized by a beneficial directionality for etching. The capacitive source may produce increased flux and energy, which may afford improved etching. Consequently, the ICP source may be utilized to produce increased ion density, while the capacitive source may be used to produce ion flux, which together may provide improved etching capabilities over conventional techniques and chambers.

Processing system 300 may be configured to house a semiconductor substrate 355 in a processing region 333 of the chamber. The chamber housing 303 may at least partially define an interior region of the chamber. For example, the chamber housing 303 may include lid 302, and may at least partially include any of the other plates or components illustrated in the figure. For example, the chamber components may be included as a series of stacked components with each component at least partially defining a portion of chamber housing 303. The substrate 355 may be located on a pedestal 356 or substrate support as shown, which may extend into the processing region 333, and may be configured to position, heat, chuck, or otherwise support substrate 355 for processing. Processing system 300 may include a remote plasma unit coupled with inlet 301. In other embodiments, the system may not include a remote plasma unit.

With or without a remote plasma unit, the system may be configured to receive precursors or other fluids through inlet 301, which may provide access to a mixing region 311 of the processing chamber. The mixing region 311 may be separate from and fluidly coupled with the processing region 333 of the chamber. The mixing region 311 may be at least partially defined by a top of the chamber of system 300, such as chamber lid 302 or lid assembly, which may include an inlet assembly for one or more precursors, and a distribution device, such as faceplate 309 below. Faceplate 309 may include or define a plurality of channels or apertures 307 that may be positioned and/or shaped to affect the distribution and/or residence time of the precursors in the mixing region 311 before proceeding through the chamber.

For example, recombination may be affected or controlled by adjusting the number of apertures, size of the apertures, or configuration of apertures across the faceplate 309. Spacer 304, such as a ring of dielectric material may be positioned between the top of the chamber and the faceplate 309 to further define the mixing region 311. Additionally, spacer 304 may be metallic or otherwise conductive to allow electrical coupling of lid 302 and faceplate 309. Additionally, spacer 304 may not be included, and either lid 302 or faceplate 309 may be characterized by extensions or raised features to separate the two plates to define mixing region 311. As illustrated, faceplate 309 may be positioned between the mixing region 311 and the processing region 333 of the chamber, and the faceplate 309 may be configured to distribute one or more precursors through the system 300.

The chamber of system 300 may include one or more of a series of components that may optionally be included in disclosed embodiments. For example although faceplate 309 is described, in some embodiments the chamber may not include such a faceplate. In disclosed embodiments, the precursors that are at least partially mixed in mixing region 311 may be directed through the chamber via one or more of the operating pressure of the system, the arrangement of the chamber components, or the flow profile of the precursors.

An additional device or plate 323 may be disposed below the faceplate 309. Plate 323 may include a similar design as faceplate 309, for example, or may have differently distributed apertures in some embodiments. Spacer 310 may be positioned between the faceplate 309 and plate 323, and may include a dielectric material, but may also include a conductive material allowing faceplate 309 and plate 323 to be electrically coupled in embodiments. Apertures 324 may be defined in plate 323, and may be distributed and configured to affect the flow of ionic species through the plate 323. For example, the apertures 324 may be configured to at least partially suppress the flow of ionic species directed toward the processing region 333, and may allow plate 323 to operate as an ion suppressor as previously described. The apertures 324 may have a variety of shapes including channels as previously discussed, and may include a tapered portion extending outward away from the processing region 333 in disclosed embodiments.

The chamber of system 300 optionally may further include a gas distribution assembly 325 within the chamber. The gas distribution assembly 325, which may be similar in aspects to the dual-channel showerheads as previously described, may be located within the chamber above the processing region 333, such as between the processing region 333 and the lid 302. The gas distribution assembly 325 may be configured to deliver both a first and a second precursor into the processing region 333 of the chamber in some embodiments. The gas distribution assembly 325 or showerhead may at least partially divide the interior region of the chamber into a remote region and a processing region in which substrate 355 is positioned. Although the exemplary system of FIG. 3 includes a dual-channel showerhead, it is to be understood that alternative distribution assemblies may be utilized that maintain a precursor fluidly isolated from species introduced through inlet 301. For example, a perforated plate and tubes underneath the plate may be utilized, although other configurations may operate with reduced efficiency or not provide as uniform processing as the dual-channel showerhead as described. By utilizing one of the disclosed designs, a precursor may be introduced into the processing region 333 that may not be excited by a plasma prior to entering the processing region 333, or may be introduced to avoid contacting an additional precursor with which it may react. Although not shown, an additional spacer may be positioned between the plate 323 and the showerhead, such as an annular spacer, to isolate the plates from one another. In embodiments in which an additional precursor may not be included, the gas distribution assembly 325 may have a design similar to any of the previously described components, such as a faceplate or perforated plate as illustrated or described elsewhere.

In embodiments, gas distribution assembly 325 may include an embedded heater 329, which may include a resistive heater or a temperature controlled fluid, for example. The gas distribution assembly 325 may include an upper plate and a lower plate. The plates may be coupled with one another to define a volume 327 between the plates. The coupling of the plates may be such as to provide first fluid channels 340 through the upper and lower plates, and second fluid channels 345 through the lower plate. The formed channels may be configured to provide fluid access from the volume 327 through the lower plate, and the first fluid channels 340 may be fluidly isolated from the volume 327 between the plates and the second fluid channels 345. The volume 327 may be fluidly accessible through a side of the gas distribution assembly 325, such as channel 223 as previously discussed. The channel may be coupled with an access in the chamber separate from the inlet 301 of the system 300. The chamber of system 300 may also include a chamber liner 335, which may protect aspects of the chamber from plasma effluents as well as material deposition, for example. The liner may be or may include a conductive material, and in embodiments may be or include an insulative material.

In some embodiments, a plasma as described earlier may be formed in a region of the chamber defined between two or more of the components previously discussed. For example, a plasma region such as a first plasma region 315, may be formed between faceplate 309 and plate 323. Spacer 310 may maintain the two devices electrically isolated from one another in order to allow a plasma field to be formed. Faceplate 309 may be electrically charged while plate 323 may be grounded or DC biased to produce a plasma field within the region defined between the plates. The plates may additionally be coated or seasoned in order to minimize the degradation of the components between which the plasma may be formed. The plates may additionally include or be coated with compositions that may be less likely to degrade or be affected including ceramics, metal oxides, or other conductive materials.

Operating a conventional capacitively-coupled plasma (“CCP”) may degrade the chamber components, which may remove particles that may be inadvertently distributed on a substrate. Such particles may affect performance of devices formed from these substrates due to the metal particles that may provide short-circuiting across semiconductor substrates. However, the CCP of the disclosed technology may be operated at reduced or substantially reduced power in embodiments, and may be utilized to maintain the plasma, instead of ionizing species within the plasma region. In other embodiments the first CCP in this region may be operated to ionize precursors delivered into the region. For example, the CCP may be operated at a power level below or about 1 kW, 500 W, 250 W, 100 W, 50 W, 20 W, etc. or less. Moreover, the CCP may produce a flat plasma profile which may provide a uniform plasma distribution within the space. As such, a more uniform flow of plasma effluents may be delivered downstream to the processing region of the chamber.

The chamber of system 300 may also include an additional plasma configuration including multiple aspects or sources within the chamber housing. For example, plasma source 350 may be an inductively-coupled plasma (“ICP”) source in embodiments. As illustrated, the ICP source 350 may be included between the gas distribution assembly 325 and the pedestal 356. The ICP source 350 may be positioned about the processing region 333, and may at least partially define the processing region 333 radially or laterally. The ICP source may include a combination of materials in embodiments, or may be a single material design. As a combination, ICP source 350 may include a conductive material 354 that is included within a dielectric material 352, or contained or housed within the dielectric material 352. In some embodiments, the dielectric material 352 may include any number of dielectric or insulative materials. For example, dielectric material 352 may be or include aluminum oxide, yttrium oxide, quartz, single crystalline silicon, or any other insulating material that may function within the processing environment. Some materials may not operate effectively as the dielectric material 352 in embodiments in which the ICP source 350 is positioned near or partially defining the processing region. For example, in some embodiments as illustrated, ICP source 350 may form a portion of sidewalls of the chamber housing. Because the ICP source 350 may be exposed to one or more precursors or plasma effluents, the choice of material for the dielectric material 352 may be related to the precursors or operations to which it will be exposed.

The conductive material 354 may be any conductive material that may carry current. Conductive material 354 may include a solid material or a hollow material, such as a tube. By utilizing a tube, for example, a fluid may be flowed through the hollow structure, which may aid in cooling of the source under charge. In embodiments the conductive material 354 may be configured to receive a fluid flowed within the tube. The fluid may be water, for example, or may be any other fluid that may not impede the function of the ICP source 350 during operation. The conductive material 354 may be any conductive material that may operate effectively at varying operating conditions. In one non-limiting example, the conductive material 354 may be copper, including a copper tube, although other conductive materials such as other metals, or conductive non-metals may be used. Conductive material 354 may be included in a number of configurations. In some configurations, the conductive material may be a tube, which may be wound, spiraled, or coiled within the dielectric material 352, and thus may be located throughout the dielectric material 352. For example, as illustrated, conductive material 354 may be incorporated as a coil extending vertically within dielectric material 352. The coil may be wound in any number of turns, and may include at least one complete turn, at least two complete turns, at least three complete turns, at least four complete turns, or more. The conductive material 354 may be included in a relatively uniform or uniform configuration to produce a uniform plasma across the ICP source 350, for example.

The number of turns of the conductive material 354 or ICP coil may impact the power provided by the ICP source. For example, a higher number of turns of the conductive material may provide an increased power to the plasma. However, as the number of turns continues to increase, this advantage may begin to decrease. For example, as turns continue to increase, the coil may begin to compensate and induce a self-inductance, or effectively resisting itself. Accordingly, by reducing the turns below such a threshold, or minimizing the effect, as well as providing enough turns for adequate power, a balance may be established to provide acceptable ICP sources. Additionally, the configuration of the conductive material 354 may be to include similar coverage across the dielectric material 352 to provide a more uniform plasma profile through the ICP source. Consequently, in some embodiments, conductive material 354 may have less than seven complete turns, and may have less than six complete turns, less than five complete turns, or less.

As previously noted, ICP source 350 may be positioned below the fluid delivery sources, such as gas distribution assembly 325 as well as other diffusers, faceplates, or showerheads previously discussed. ICP source 350 may be an annular component in some embodiments, and when positioned about a portion of processing region 333, or proximate substrate 355, a uniform flow of materials may enter a region defined by ICP source 350, which may produce a more uniform profile of plasma effluents within the processing region. The gas distribution assembly 325 or showerhead may be grounded in some embodiments as illustrated, and thus with a charged ICP source 350, the gas distribution assembly 325 may cause electromagnetic losses from the ICP source 350. Accordingly, a gap distance between the two components may be maintained in some embodiments.

Hence, in some embodiments an additional spacer 360 may be positioned between the ICP source 350 and the gas distribution assembly 325. In some embodiments, spacer 360 may be a portion of dielectric material 352, of ICP source 350, where conductive material 354 may be maintained in a distal portion from the faceplate, or separated by a spacer of that length. For example, the conductive material 354 may be maintained beyond 30% of a height of dielectric material 352 from the showerhead, when extending between sidewalls 305 and gas distribution assembly 325, and may be maintained beyond 35% of the height from the showerhead, beyond 40% of the height from the showerhead, beyond 45% of the height from the showerhead, beyond 50% of the height from the showerhead, or further, as well as maintained that relative distance with a spacer 360. An additional spacer 362 may optionally be included between ICP source 350 and liner 335 in some embodiments, which may provide additional structural support and protection for the ICP source. Any of the spacers may be or include any of the dielectric materials described previously, and may be the same or different materials from one another in some embodiments.

In some embodiments, gas distribution assembly 325 may be operated as an electrode for a capacitively-coupled plasma (“CCP”) formed through the processing region between the showerhead and the pedestal 356. For example, pedestal 356 may include an electrode 365, which may be coupled with an RF power source 367 for generating a capacitively-coupled plasma relative to grounded gas distribution assembly 325 and grounded sidewalls 305. By including both ICP and CCP power, ion density can be decoupled from ion flux, and the two sources may be operated independently to produce a wide range of plasma conditions, which may afford greater etch flexibility from slight trimming and milling, to more extensive etching through structures either isotropically or anisotropically.

Liner 335 may extend as an inverted bowl-shaped component within the processing chamber, and may be seated on sidewalls 305 of chamber housing 303 radially inward of ICP source 350. Liner 335 may be or include any of the dielectric or ceramic materials previously described, and may protect chamber components during processing. Because a CCP source may still be operated through the processing region, during certain processing operations chamber sputtering may still be a challenge, and thus including a liner may protect components of the system. Liner 335 may extend both radially or laterally across gas distribution assembly 325 or the showerhead, and may also extend across the ICP source 350. For example, a first portion 336 of liner 335 may extend across the ICP source 350, as well as any spacers, when included in the system.

Additionally, a second portion 337 may extend across a surface of the gas distribution assembly 325, such as the surface facing the processing region 333. Second portion 337 of liner 335 may define a plurality of apertures 338 through the liner, which may provide fluid access into the processing region. As illustrated, apertures 338 may be axially aligned with apertures of the gas distribution assembly 325, or may be expressly aligned off-axis with each aperture of the gas distribution assembly, which may afford further gas distribution in some embodiments. A gap may be maintained between the showerhead and the liner to allow fluid flow or distribution before passing through the liner. In some embodiments, liner 335 may be maintained a distance less than a few millimeters from the faceplate, or less than a distance at which plasma may form between the showerhead and the liner.

By including an ICP source 350, such as illustrated, a lower voltage may be produced than with a capacitively-coupled plasma, and in some embodiments in which both sources are operated, the sheath voltage may be reduced further than without an ICP source. In a capacitively-coupled plasma, the voltage induced on the electrodes may be directly proportional to the power, and thus may generate high voltages even at reduced power. For example, an exemplary capacitive source may be operated at a relatively low power level of about 50 W and at a pressure of about 20 mTorr, but may induce a voltage of over 200 volts, and may induce a voltage of about 300-400 volts on the plates of the capacitive source. This may produce the sputtering previously discussed, for example. An inductively-coupled plasma source operated at the same frequency, such as ICP source 550, for example, may produce an induced voltage less than 300 volts, for example, and may be less than 250 volts, less than 200 volts, less than 175 volts, less than 150 volts, less than 125 volts, less than 100 volts, less than 90 volts, less than 80 volts, less than 70 volts, less than 60 volts, less than 50 volts, or less depending on the number of turns and other parameters.

Moreover, when operated together, the ICP source may increase ion density within the processing region, such as by an order of magnitude or more, which may reduce the sheath potential formed by the CCP plasma electrodes, and limit bombardment and sputtering of chamber components. For example, when the ICP source is not engaged, or engaged at lower power, a sheath potential of well over 300 V may be produced, which may damage chamber components. As the ICP source power is increased, when reducing the CCP power or even while maintaining the CCP power, the sheath potential may be reduced below or about 200 V, below or about 100 V, below or about 50 V, or less, because of the greater ion density produced by the ICP source.

Utilizing ICP source 350 may provide an additional advantage over a capacitively-coupled source as discussed previously. A capacitively-coupled plasma may utilize two electrodes, which can include, for example, a showerhead as well as the wafer pedestal. Thus, ion density and ion energy at the wafer level are determined together. With an ICP source, the ion energy at the wafer level may be decoupled from the ion density of the plasma. For example, an ICP source may utilize an antenna to ionize gas, and may determine the ion density, which may be a function of power. Accordingly, an ICP source at a particular power may define the ion density of the plasma produced. The system, however, may still include the RF electrode in the pedestal, and may utilize a ground source, such as chamber walls and/or a showerhead.

By utilizing an RF electrode and electrical ground separate from the antenna defining the ion density, the ion energy may be controlled separately at the wafer level by this RF bias at the wafer level. Accordingly, embodiments of the present design may provide additional control and tuning over process activities by utilizing the ICP source to determine ion density of the plasma, and then using a CCP source to control ion energy. When a small RF bias is applied, intricate removal and milling may be performed, while when CCP power is increased to several hundred watts, increased etching may be performed through structures. While this CCP power in conventional systems may damage chamber components, when utilized with ICP source 350, increased ion density may reduce the sheath potential formed, which may further protect chamber components at higher power.

Accordingly, in some embodiments a power source coupled with the pedestal electrode may operate at up to or greater than or about 50 W, and may operate at greater than or about 100 W, greater than or about 200 W, greater than or about 300 W, greater than or about 400 W, greater than or about 500 W, greater than or about 600 W, or higher, although the power may be maintained below a few kilowatts or less, as damage may occur at that power level. Because ICP sources may not produce the sheath potential of CCP sources, ICP sources in some embodiments may be operated at up to or greater than or about 50 W, and may be operated at greater than or about 100 W, greater than or about 200 W, greater than or about 300 W, greater than or about 400 W, greater than or about 500 W, greater than or about 600 W, greater than or about 800 W, greater than or about 1.0 kW, greater than or about 1.5 kW, greater than or about 2.0 kW, greater than or about 2.5 kW, greater than or about 3.0 kW, greater than or about 3.5 kW, greater than or about 4.0 kW, greater than or about 4.5 kW, greater than or about 5.0 kW, or higher, which may provide the capability for enhanced etching through structures. Either source may be operated at any number of frequencies such as greater than or about 13 MHz, greater than or about 27 MHz, greater than or about 40 MHz, greater than or about 60 MHz, or greater.

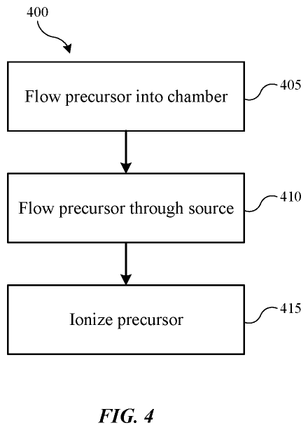

The chambers and plasma sources described above may be used in one or more methods. FIG. 4 shows operations of an exemplary method 400 according to some embodiments of the present technology. The method may involve operations in an ion etching operation in which radical species may be directed to a surface of a wafer to etch or modify features on the wafer. Method 400 may include flowing a precursor into a chamber at operation 405. The chamber may be any of the chambers previously described, and may include one of the exemplary plasma sources, such as an ICP plasma source, as previously described. The precursor may be or include materials that may not chemically react with a surface of the wafer, and may include, for example, hydrogen, helium, argon, nitrogen, or some other precursor. In some embodiments chemically reactive precursors may be used, such as halogen-containing materials, oxygen-containing materials, or any number of precursors for etching. The precursor may flow through the chamber to a plasma source, such as one of the CCP and/or ICP sources, at operation 410. The plasma source may receive power to produce a plasma through the source, which may ionize the precursor at operation 415 as the precursor flows through the region encompassed or defined by the source. An upstream or remote CCP source may be operated as previously explained, as well as an ICP source operated at the processing region. A capacitively-coupled plasma may be produced in conjunction with operation of the ICP source between the pedestal and showerhead as previously described, which may direct ions towards the substrate for etching.

In some embodiments a source, such as any of the ICP sources discussed, may also maintain plasma effluents produced elsewhere. For example, the plasma sources as described may be used to generate a plasma that may tune or further enhance plasma effluents produced in a capacitively-coupled plasma upstream of the source, or in an external source, such as a remote plasma unit. In this way precursors that may have relatively short residence times, for example, may be maintained by the ICP plasma of a source near a processing region or near the wafer level. By incorporating an ICP source according to embodiments of the present technology, broader etch applications may be performed, with higher ion density.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a layer” includes a plurality of such layers, and reference to “the precursor” includes reference to one or more precursors and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing chamber comprising:
a chamber housing at least partially defining an interior region of the semiconductor processing chamber;
a showerhead positioned within the chamber housing, wherein the showerhead at least partially separates the interior region into a remote region and a processing region, and wherein sidewalls of the chamber housing at least partially define the processing region;
a substrate support extending into the processing region and configured to support a substrate; and
an inductively-coupled plasma source positioned between the showerhead and the substrate support, wherein the inductively-coupled plasma source comprises a conductive material disposed within a dielectric material, and wherein the inductively-coupled plasma source forms a portion of the sidewalls of the chamber housing.

2. The semiconductor processing chamber of claim 1, wherein the dielectric material is selected from the group consisting of aluminum oxide, yttrium oxide, single crystalline silicon, and quartz.

3. The semiconductor processing chamber of claim 1, wherein the substrate support comprises an electrode operable to form a capacitively-coupled plasma within the processing region.

4. The semiconductor processing chamber of claim 3, wherein the showerhead is coupled with electrical ground and operable as a second electrode configured to produce a capacitively-coupled plasma within the processing region.

5. The semiconductor processing chamber of claim 1, further comprising a liner extending across the showerhead and along the sidewalls of the chamber housing, wherein the liner extends across the inductively-coupled plasma source.

6. The semiconductor processing chamber of claim 5, wherein the liner comprises a dielectric material selected from the group consisting of aluminum oxide, yttrium oxide, single crystalline silicon, and quartz.

7. The semiconductor processing chamber of claim 5, wherein the liner extends across a surface of the showerhead facing the processing region, and wherein the liner defines a plurality of apertures through the liner.

8. The semiconductor processing chamber of claim 1, wherein the conductive material is configured in a coil extending vertically within the dielectric material for at least two complete turns of the conductive material.

9. The semiconductor processing chamber of claim 1, further comprising a spacer positioned between the showerhead and the inductively-coupled plasma source.

10. A semiconductor processing chamber comprising:
a chamber housing at least partially defining a processing region of the semiconductor processing chamber, wherein the chamber housing includes a lid assembly defining an inlet for receiving precursors into the semiconductor processing chamber, and wherein the chamber housing comprises sidewalls extending about the processing region;
a pedestal extending within the processing region of the semiconductor processing chamber and configured to support a substrate for processing;
a showerhead positioned within the chamber housing, wherein the showerhead is positioned between the lid assembly and the pedestal; and
an inductively-coupled plasma source positioned between the showerhead and the pedestal, wherein the inductively-coupled plasma source comprises a conductive material within a dielectric material.

11. The semiconductor processing chamber of claim 10, wherein the inductively-coupled plasma source comprises an annular component disposed as a portion of the chamber housing.

12. The semiconductor processing chamber of claim 11, wherein the inductively-coupled plasma source is seated on the sidewalls of the chamber housing.

13. The semiconductor processing chamber of claim 12, further comprising a liner extending radially inward of the inductively-coupled plasma source, wherein the liner is seated on the sidewalls of the chamber housing.

14. The semiconductor processing chamber of claim 13, wherein the liner comprises a first portion extending across the inductively-coupled plasma source, and wherein the liner comprises a second portion extending across the showerhead.

15. The semiconductor processing chamber of claim 14, wherein the second portion defines a plurality of apertures through the liner.

16. The semiconductor processing chamber of claim 15, wherein a gap is defined between the showerhead and the second portion of the liner.

17. The semiconductor processing chamber of claim 10, wherein the pedestal comprises an electrode operable to form a capacitively-coupled plasma within the processing region.

18. The semiconductor processing chamber of claim 10, wherein the showerhead is coupled with electrical ground and operable as a second electrode configured to produce a capacitively-coupled plasma within the processing region.

19. The semiconductor processing chamber of claim 10, wherein the sidewalls of the chamber housing are coupled with electrical ground.

20. A semiconductor processing chamber comprising:
a chamber housing at least partially defining a processing region of the semiconductor processing chamber, wherein the chamber housing comprises a lid, and wherein the chamber housing comprises sidewalls;
a pedestal extending within the processing region of the semiconductor processing chamber and configured to support a substrate for processing;
a showerhead positioned within the chamber housing, wherein the showerhead is positioned between the lid and the pedestal;
an inductively-coupled plasma source positioned between the showerhead and the pedestal, wherein the inductively-coupled plasma source comprises a conductive material within a dielectric material, and wherein the inductively-coupled plasma source is seated on the sidewalls of the chamber housing; and
a liner seated on the sidewalls of the chamber housing radially inward of the inductively-coupled plasma source.
